(19) United States
(12) Patent Application Publication
(10) Pub. No.: US 2007/0059880 A1
(43) Pub. Date: Mar. 15, 2007

(54) HSG PROCESS AND PROCESS OF FABRICATING LARGE-AREA ELECTRODE

(76) Inventors: Li-Fang Yang, Taipei City (TW); Kun-Shu Huang, Taoyuan County (TW); Sheng-Hsiu Peng, Taoyuan County (TW); Tzung-Hua Ying, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,534

(22) Filed: Sep. 14, 2005

(51) Int. Cl. H01L 21/8242; H01L 21/20

(52) U.S. Cl. 438/253; 438/256; 438/396; 438/399; 257/E21.012

(57) ABSTRACT

A hemispherical silicon grain (HSG) process is described. A doped poly-Si layer is formed on a substrate, and then an oxidative gas is used to oxidize the surface of the doped poly-Si layer to form an oxide layer. An a-Si layer is then formed on the oxide layer, and the a-Si layer is converted into HSG.

### BACKGROUND OF THE INVENTION

1. Field of the Invention

The present invention relates to a semiconductor process. More particularly, this invention relates to a hemispherical silicon grain (HSG) process and a process of fabricating a large-area electrode through the HSG process.

2. Description of the Related Art

In an integrated circuit, many electrodes are fabricated using doped poly-Si including, for example, the gate of a MOS device, the storage electrode of a dynamic random access memory (DRAM) and the floating gate of a programmable non-volatile memory. In particular, hemispherical silicon grains can be formed on the storage electrode of a DRAM cell to increase the capacitance of the storage capacitor and boost the performance of the DRAM device.

Except the poly-Si electrode of a storage capacitor, hemispherical silicon grains can also be form on other types of poly-Si electrodes requiring a higher capacitance so that a large-area electrode is produced. For example, HSG may form on the poly-Si floating gate of a non-volatile memory cell to increase the gate coupling ratio (GCR).

One of the conventional methods of forming HSG on a doped poly-Si gate includes the following steps. First, the native oxide layer on the surface of a poly-Si electrode is removed using dilute hydrofluoric acid (DHF) solution. Then, wet oxidation is conducted to oxidize the surface of the poly-Si electrode with H₂O₂ to form a thin oxide layer. Then, an amorphous silicon (a-Si) layer is deposited on the oxide layer and converted into HSG. The thin oxide layer serves to restrain the dopant diffusion from the poly-Si layer to the a-Si layer and prevent the dopants from hindering recrystallization of the a-Si layer. Also, the thin oxide layer has a small thickness so that the electrical connection between the HSG and the poly-Si layer is not hindered.

However, since wet oxidation is inserted between the high-temperature deposition processes for forming the poly-Si layer and the a-Si layer, the fabricating process is rather complicated and the processing time (Q-time) is difficult to control. Moreover, the DHF solution for removing the native oxide can easily seep through the poly-Si grain gaps to corrode the underlying oxide layer, especially when the poly-Si layer is rather thin.

For example, in the process of fabricating the lower electrode of a crown capacitor of a DRAM cell, a thin poly-Si layer is usually formed in an opening in an oxide layer. The thinness of the poly-Si layer is for raising the capacitance of capacitor and preventing the HSG formed later from blocking the opening and leading to difficulty in filling of the dielectric material and upper-electrode material into the opening. Yet, the thinness of the poly-Si layer renders the underlying oxide layer more vulnerable to the corrosive attack of the DHF and increases the probability of causing a current leakage in the capacitor.

### SUMMARY OF THE INVENTION

Accordingly, at least one object of this invention is to provide a method of forming HSG capable of solving the aforementioned problems.

Another object of this invention is to provide a process for forming a large-area electrode that utilizes the HSG process of this invention.

To achieve these and other advantages and in accordance with the purpose of the invention, as embodied and broadly described herein, the invention provides an HSG process including the following steps. First, a doped poly-Si layer is formed on a substrate. An oxidative gas is used to oxidize the surface of the doped poly-Si layer to form an oxide layer. Then, an a-Si layer is formed on the oxide layer. Thereafter, the a-Si layer is converted into multiple hemispherical silicon grains. The oxide layer has a thickness small enough not to hinder the electrical connection between the hemispherical silicon grains and the doped poly-Si layer.

In one preferred embodiment, the oxidative gas includes oxygen gas (O₂), for example. Furthermore, the doped poly-Si layer, the oxide layer and the amorphous layer can be formed in the same reaction chamber in a continuous manner. The doped poly-Si layer is formed at a first temperature and the a-Si layer is formed at a second temperature, wherein the second temperature is lower than the first temperature. The method of forming the oxide layer may include diffusing the oxidative gas into the reaction chamber between the step of forming the doped poly-Si layer and the step of forming the a-Si layer.

In the aforementioned preferred embodiment, the temperature inside the reaction chamber is gradually lowered from the first temperature to the second temperature after the poly-Si layer is formed. When the temperature inside the reaction chamber is lowered almost down to the second temperature, the step of diffusing the oxidative gas into the reaction chamber is carried out. The first temperature is preferably between 560° C. and 590° C. and the second temperature is preferably between 500° C. and 530° C.

Furthermore, the method of converting the a-Si layer into HSG may include the following steps. First, crystal seeds are formed on the a-Si layer. Then, an annealing step is conducted to recrystallize the a-Si based on the crystal seeds to form HSG.

In addition, in some embodiments, the substrate further includes a dielectric layer. The dielectric layer has a contact and an opening exposing the contact therein. The doped poly-Si layer is substantially conformal to the dielectric layer and the opening therein. The doped poly-Si is used to build the lower electrode of a crown-shaped capacitor.

In the aforementioned process for forming HSG, the doped poly-Si layer may be a phosphorous-doped poly-Si layer, for example.

The present invention also provides a method of fabricating a large-area electrode, which is based on the aforementioned HSG process and includes the following steps. First, a dielectric layer having a contact therein is provided. An opening that exposes the contact is formed in the dielectric layer. Then, a doped poly-Si layer substantially conformal to the dielectric layer and the opening is formed over the dielectric layer. Thereafter, an oxidative gas is used to oxidize the surface of the doped poly-Si layer to form an oxide layer. After that, a conformal a-Si layer is formed over the oxide layer, and then the a-Si layer is converted into HSG. The oxide layer is thin enough not to hinder the electrical connection between the HSG and the doped poly-Si layer.

In one preferred embodiment, the aforementioned large-area electrode is the lower electrode of a crown-shaped capacitor of a DRAM cell.

Furthermore, in the process of fabricating a large-area electrode, other features concerning the oxidative gas, the doped poly-Si layer, the oxide layer, the a-Si layer and the HSG can be the same as those in the aforementioned HSG process.

In this invention, the thin oxide layer is formed by oxidizing the surface of a poly-Si layer using an oxidative gas. Hence, the processes for forming the poly-Si layer, the oxide layer and the a-Si layer are easily integrated. In one preferred embodiment, the integrative process for forming the poly-Si layer and the a-Si layer is carried out inside the same reaction chamber, and the oxidative gas is diffused into the reaction chamber between the step of forming the poly-Si layer and the step of forming the a-Si layer so that a thin oxide layer is grown on the surface of the poly-Si layer. As a result, the HSG process of this invention is simpler to control, and the Q-time is easier to control. Furthermore, since no DHF solution is applied to treat the surface of the poly-Si layer, the underlying oxide layer will not be corroded. Thus, a thinner poly-Si layer can be produced to meet specific requirements.

It is to be understood that both the foregoing general description and the following detailed description are exemplary, and are intended to provide further explanation of the invention as claimed.

### BRIEF DESCRIPTION OF THE DRAWINGS

FIG. 1 is a graph showing the temperature profile for forming a doped poly-Si layer, an oxide layer and an a-Si layer in an HSG process according to a preferred embodiment of this invention.

FIGS. 2A through 2D are schematic cross-sectional views showing the steps for forming a large-area electrode according to the preferred embodiment of this invention.

### DESCRIPTION OF THE PREFERRED EMBODIMENTS

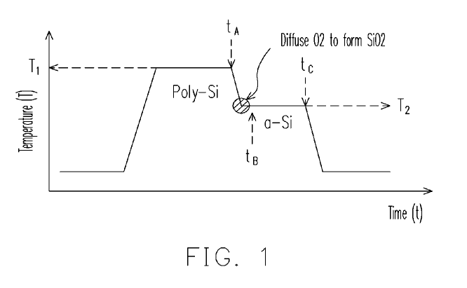

FIG. 1 is a graph showing the temperature profile for forming a doped poly-Si layer, an oxide layer and an a-Si layer in a HSG process according to the preferred embodiment of this invention. The poly-Si layer, the oxide layer and the a-Si layer are formed in the same reaction chamber, and the oxidative gas used is O₂, for example. However, other oxidative gases that can oxidize silicon at a high temperature can also be used.

As shown in FIG. 1, the temperature inside the reaction chamber is firstly raised to T₁ for depositing a doped poly-Si layer having a thickness preferably of 150 Å±10%. The dopant used is phosphorus, for example. The deposition conditions for the doped poly-Si layer include a temperature of about 577.5° C., a pressure of about 0.43 Torr and a depositing gas containing silane (SiH₄) and phosphine (PH₃) with flow rates of about 2500 slm and about 600 slm, respectively.

Then, the temperature inside the reaction chamber is reduced from T₁ to a lower temperature T₂ for depositing a-Si. As the temperature drops almost to T₂, O_{2(g)} or other suitable oxidative gas is briefly diffused into the reaction chamber so that a thin oxide layer is formed on the poly-Si layer. The oxide layer preferably has a thickness of about 30-40 Å. The oxide layer with such a small thickness will be damaged during the step of converting the a-Si into HSG, so that the electrical connection between the doped poly-Si layer and the HSG is not hindered. Thereafter, an a-Si deposition process is carried out at the temperature T₂ to form an a-Si layer on the thin oxide layer. The a-Si layer preferably has a thickness of about 250 Å±10%. The deposition conditions includes a temperature of about 517.5° C., a pressure of about 0.60 Torr and a depositing gas containing silane (SiH₄) with a flow rate of about 800 slm.

After the a-Si layer is deposited, the a-Si layer is converted into HSG. The method of converting the a-Si into HSG includes seeding silicon crystals on the a-Si layer and performing an annealing step using the crystal seeds to initiate recrystallization, thereby converting the a-Si layer into HSG. Because such a method can be seen in many references, a detailed description is omitted.

Furthermore, in a practical process design, the step for depositing the doped poly-Si layer and the step for depositing the a-Si layer can be respectively optimized. Meanwhile, the step of diffusing an oxidative gas like O₂ can be inserted between the two deposition processes after all parameters for the two deposition processes are properly adjusted.

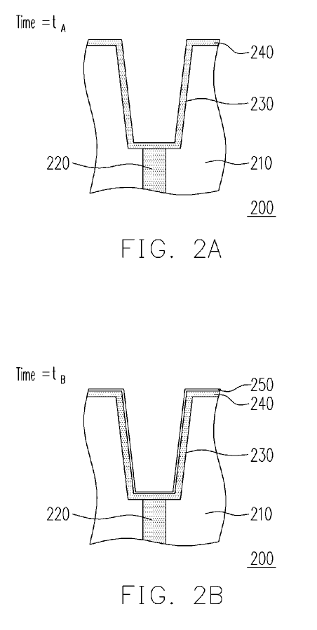

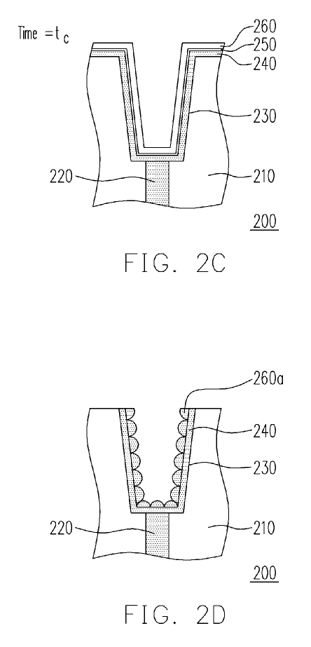

FIGS. 2A through 2D are schematic cross-sectional views showing the steps for forming a large-area electrode according to the preferred embodiment of this invention. The large-area electrode is the lower electrode of a crown-shaped capacitor of a DRAM cell, for example. Furthermore, the process can utilize the above HSG process.

As shown in FIG. 2A, a substrate 200 having a dielectric layer 210 like a SiO layer thereon is provided. The dielectric layer 210 has a contact 220 therein, which is formed from doped poly-Si, for example. An opening 230 that exposes the top of the contact 220 is formed in the dielectric layer 210, and then a doped poly-Si layer 240 substantially conformal to the profile of the dielectric layer 210 and the opening 230 is formed over the substrate 200. The doped poly-Si layer 240 is in contact with the contact 220 for electrical connection. In addition, the dopant type, overall thickness and other conditions necessary for forming the doped poly-Si layer 240 are identical to the aforementioned.

As shown in FIG. 2B, an oxidative gas like O₂ is used to oxidize the surface of the poly-Si layer 240 and form a thin oxide layer 250. The thin oxide layer 250 preferably has a thickness of about 30-40 Å, and the method and conditions for forming the thin oxide layer 250 are identical to the aforementioned. Then, as shown in FIG. 2C, a substantially conformal a-Si layer 260 is formed on the thin oxide layer 250. The thickness and deposition conditions of the a-Si layer 260 are identical to the aforementioned.

As shown in FIG. 2D, the a-Si layer 260 is converted into HSG 260a using a method similar to the aforementioned. Because the thin oxide layer 250 with a thickness of 30-40 Å will be damaged in the conversion process, the electric connection between the poly-Si layer 240 and the HSG 260a is not hindered. Thereafter, the poly-Si layer 240 and the HSG 260a outside the opening 230 is removed, for example, by filling the opening 230 with a protective material like a photoresist material and then performing a chemical mechanical polishing (CMP) step or an etching-back step. Hence, the poly-Si layer 240 and the HSG 260a not covered by the protective material are removed. Up to this point, the process for fabricating a large-area electrode according to the preferred embodiment of this invention is complete.

It is noted that when the process for forming the doped poly-Si layer, the oxide layer and the a-Si layer follows the one shown in FIG. 1, FIGS. 2A, 2B and 2C correspond to the respective structures at time t_{A}, t_{B} and t_{C} in FIG. 1.

As mentioned above, the HSG process of the preferred embodiment of this invention forms the poly-Si layer and the a-Si layer in the same reaction chamber. Moreover, an oxidative gas like O₂ is diffused into the chamber between the step of forming the poly-Si layer and the step of forming the a-Si layer, so as to oxidize the surface of the poly-Si layer and form a thin oxide layer. As a result, the HSG process is simpler and the Q-time is easier to control in this invention.

Furthermore, since no DHF solution is applied to the surface of the poly-Si layer, the underlying oxide layer is not corroded, so that the poly-Si layer is allowed to form thinner for certain requirements. For example, in a process of forming a lower electrode of a crown capacitor of DRAM, a thinner poly-Si layer formed inside the template opening can increase the capacitance as well as prevent the HSG formed later from blocking the subsequent filling materials including the dielectric material and the upper-electrode material of the capacitor.

It will be apparent to those skilled in the art that various modifications and variations can be made to the structure of this invention without departing from the scope or spirit of the invention. In view of the foregoing, it is intended that this invention cover modifications and variations of this invention provided they fall within the scope of the following claims and their equivalents.

1. A process of forming hemispherical silicon grains (HSG) in a reaction chamber, comprising:
providing a substrate;
forming a doped poly-Si layer on the substrate;
oxidizing a surface of the doped poly-Si layer using an oxidative gas to form an oxide layer;
forming an a-Si layer on the oxide layer; and
converting the a-Si layer into HSG, wherein a first temperature is set in the reaction chamber to form the doped poly-Si layer and a second temperature is set to form the a-Si layer, wherein the first temperature is higher than the second temperature.

2. The process of claim 1, wherein the oxidative gas comprises O₂.

3. The process of claim 1, wherein
the doped poly-Si layer, the oxide layer and the a-Si layer are formed in the same reaction chamber in a continuous manner; and
the step of forming the oxide layer comprises: diffusing the oxidative gas into the reaction chamber alter the poly-Si layer is formed but before the a-Si layer is formed.

4. The process of claim 3, wherein the oxidative gas comprises O₂.

5. The process of claim 3, wherein the temperature inside the reaction chamber is gradually lowered from the first temperature to the second temperature after the poly-Si layer is formed, and the step of diffusing the oxidative gas into the reaction chamber is conducted when the temperature has almost reached the second temperature.

6. The process of claim 3, wherein the first temperature is about 560-590° C.

7. The process of claim 3, wherein the second temperature is about 500-530° C.

8. The process of claim 1, wherein converting the a-Si layer into HSG comprises:
forming a plurality of crystal seeds on the a-Si layer; and
performing an annealing step to initiate recrystallization based on the crystal seeds.

9. The process of claim 1, wherein
the substrate includes a dielectric layer;
the dielectric layer has a contact therein;
the dielectric layer has an opening therein exposing the contact; and
the doped poly-Si layer is substantially conformal to the dielectric layer and die opening, and serves as a lower electrode of a capacitor.

10. The process of claim 1, wherein the doped poly-Si layer comprises a phosphorus-doped poly-Si layer.

11. A process of fabricating a large-area electrode in a reaction chamber, comprising the steps of:
providing a dielectric layer with a contact and an opening exposing the same therein;
forming a conformal doped poly-Si layer over the dielectric layer and the opening;
forming an oxide layer on the doped poly-Si layer by applying an oxidative gas;
forming a conformal a-Si layer over the oxide layer wherein a first temperature is set in the reaction chamber to form the doped poly-Si layer and a second temperature is set to form the a-Si layer, wherein the first temperature is higher than the second temperature; and
converting the a-Si layer into HSG, wherein the thickness of the oxide layer is small enough not to hinder electrical connection between the HSG and the doped poly-Si layer.

12. The process of claim 11, wherein the large-area electrode includes a lower electrode of a crown capacitor.

13. The process of claim 11, wherein the oxidative gas comprises O₂.

14. The process of claim 11, wherein
the doped poly-Si layer, the oxide layer and the a-Si layer are formed in the same reaction chamber in a continuous manner; and
the step of forming the oxide layer comprises: diffusing the oxidative gas into the reaction chamber after the poly-Si layer is formed but before the a-Si layer is formed.

15. The process of claim 14, wherein the oxidative gas comprises O₂.

16. The process of claim 14, wherein the temperature inside the reaction chamber is gradually lowered from the first temperature to the second temperature after the poly-Si layer is formed, and the step of diffusing the oxidative gas into the reaction chamber is conducted when the temperature has almost reached the second temperature.

17. The process of claim 14, wherein the first temperature is about 560-590° C.

18. The process of claim 14, wherein the second temperature is about 500-530° C.

19. The process of claim 11, wherein converting the a-Si layer into HSG comprises:
forming a plurality of crystal seeds on the a-Si layer; and
performing an annealing step to initiate recrystallization based on the crystal seeds.

20. The process of claim 11, wherein the doped poly-Si layer comprises a phosphorus-doped poly-Si layer.
